(19) United States
(12) Patent Application Publication
(10) Pub. No.: US 2009/0211640 A1
(43) Pub. Date: Aug. 27, 2009

(54) Electron injecting layer including superacid salt, lithium salt or mixture thereof, photovoltaic device including the electron injecting layer, method of manufacturing the photovoltaic device, and organic light-emitting device including the electron injecting layer

(76) Inventors: Moon-Jae Lee, Suwon-si (KR); Dae-Won Kim, Suwon-si (KR); Chang-Hee Lee, Suwon-si (KR); Ji-Young Kim, Suwon-si (KR); Jung-Ho Park, Suwon-si (KR)

Correspondence Address: ROBERT E. BUSHNELL & LAW FIRM, 2029 K STREET NW, SUITE 600, WASHINGTON, DC, 20006-1004, US

(21) Appl. No.: 12/379,247

(22) Filed: Feb. 17, 2009

(30) Foreign Application Priority Data
Feb. 26, 2008 (KR) 10-2008-0017436

(51) Int. Cl. H01L 31/042; H01J 1/62; B05D 5/12; H01B 1/00

(52) U.S. Cl. 136/263; 313/504; 427/66; 252/518.1

(57) ABSTRACT

Provided are an electron injecting layer formed by spin-coating a solution of a superacid salt, a lithium salt or a mixture thereof dissolved in a solvent, a photovoltaic device including the same, a method of manufacturing the photovoltaic device, and an organic light-emitting device including the electron injecting layer.

### CROSS-REFERENCE TO RELATED PATENT APPLICATION AND CLAIM OF PRIORITY

This application claims the benefit of Korean Patent Application No. 10-2008-0017436, filed on Feb. 26, 2008, in the Korean Intellectual Property Office, the disclosure of which is incorporated herein in its entirety by reference.

### BACKGROUND OF THE INVENTION

1. Field of the Invention

The present invention relates to an electron injecting layer (EIL) used in a photovoltaic device or an organic light emitting device (OLED), and more particularly, to an electron injecting layer (EIL) including a superacid salt, a lithium salt or a mixture thereof dissolved in a solvent which can be formed by spin-coating, a photovoltaic device including the same, an organic light-emitting device and a photovoltaic device including the electron injecting layer, and a method of manufacturing the photovoltaic device.

2. Description of the Related Art

Photovoltaic devices are devices that convert light energy into electrical signals, and can be applied in various fields such as sensors or solar cells. Photovoltaic devices are environmentally friendly and have an unlimited energy source and a long life span, and thus are being actively researched.

Meanwhile, light-emitting devices can be classified into inorganic light-emitting devices using an inorganic compound for an emitting layer, and organic light-emitting devices using an organic compound. Organic light-emitting devices have better brightness, driving voltage, and response time characteristics than inorganic light-emitting devices, and can render multi-colored displays.

Electron injecting layers (ElLs) are included in photovoltaic devices and organic light-emitting devices to provide a tunneling effect while injecting electrons from a cathode to a photoactive layer, or to reduce surface damage to an organic thin film caused by a cathode metal while forming the cathode. Such an EIL is typically formed of LiF, Liq, NaCl, CsF, Li₂O or BaO, and must be formed in an ultra-thin form, with a thickness of several nm.

However, uniformly forming the EIL to such a thickness is practically very difficult, and the process conditions must be strictly controlled therefor.

In addition, vacuum deposition used in the conventional art in order to form the EIL increases the cost of the process, and therefore increases the product price.

Therefore, development of ElLs which can overcome such problems is needed.

### SUMMARY OF THE INVENTION

The present invention provides an improved electron injecting layer.

The present invention provides an electron injecting layer (EIL) that can be formed by spin-coating.

The present invention also provides a photovoltaic device including the EIL.

The present invention also provides a method of manufacturing the photovoltaic device.

The present invention also provides an organic light-emitting device including the EIL.

According to an aspect of the present invention, there is provided an EIL including a superacid salt, a lithium salt, or a mixture thereof.

The superacid salt may be a compound represented by Formula 1 below:

M⁺X⁻(YOₘRf)ₙ <Formula 1>

wherein M⁺ is an alkaline metal cation, and Rf is a C₁-C₄ perfluoroalkyl group, Y is carbon or sulfur, and X is oxygen, nitrogen or carbon, m=1 if Y is carbon, m=2 if Y is sulfur, n=1 if X is oxygen, n=2 if X is nitrogen, and n=3 if X is carbon.

The lithium salt may be represented by Formula 2 below:

LiVW₄ <Formula 2>

wherein V is a Group 13 element, and W is a Group 17 element.

The M⁺ may preferably be a lithium cation, a sodium cation, or a potassium cation.

Rf may be trifluoromethyl (CF₃⁻) group, pentafluoroethyl (C₂F₅⁻) group, heptafluoropropyl (C₃F₇⁻) group, or perfluorobutyl (C₄F₉⁻) group.

X⁻(YOₘRf)ₙ may be bistrifluoromethanesulfonylimide (N(SO₂CF₃)₂⁻), bistrifluoromethanecarbonylimide (N(COCF₃)₂⁻), bispentafluoroethanesulfonimide (N(SOC₂F₅)₂⁻), bispentafluoroethanecarbonylimide (N(COC₂F₅)₂⁻), bisperfluorobutanesulfonylimide (N(SO₂C₄F₉)₂⁻), bisperfluorobutanecarbonylimide (N(COC₄F₉)₂⁻), tristrifluoromethanesulfonylmethide (C(SO₂CF₃)₃⁻), or tristrifluoromethanecarbonylmethide (C(COCF₃)₃⁻).

The compound represented by Formula 1 may be lithium bistrifluoromethanesulfonylimide, lithium bistrifluoromethanecarbonylimide, lithium bispentafluoroethanesulfonimide, lithium bispentafluoroethanecarbonylimide, lithium bisperfluorobutanesulfonylimide, lithium bisperfluorobutanecarbonylimide, lithium tristrifluoromethanesulfonylmethide, lithium tristrifluoromethanecarbonylmethide, sodium bistrifluoromethanesulfonylimide, sodium bistrifluoromethanecarbonylimide, sodium bispentafluoroethanesulfonimide, sodium bispentafluoroethanecarbonylimide, sodium bisperfluorobutanesulfonylimide, sodium bisperfluorobutanecarbonylimide, sodium tristrifluoromethanesulfonylmethide, sodium tristrifluoromethanecarbonylmethide, potassium bistrifluoromethanesulfonylimide, potassium bistrifluoromethanecarbonylimide, potassium bispentafluoroethanesulfonimide, potassium bispentafluoroethanecarbonylimide, potassium bisperfluorobutanesulfonylimide, potassium bisperfluorobutanecarbonylimide, potassium tristrifluoromethanesulfonylmethide, potassium tristrifluoromethanecarbonylmethide, or a mixture thereof.

V may be boron or aluminum.

W may be fluorine, chlorine, or bromine.

The compound represented by Formula 2 may be LiBF₄, LiBCl₄, LiBBr₄, LiAlF₄, LiAlCl₄ or LiAlBr₄.

According to another aspect of the present invention, there is provided a photovoltaic device including the EIL between a first electrode and a second electrode disposed opposite to each other.

According to another aspect of the present invention, there is provided a method of manufacturing an electron injecting layer, including:

preparing a solution including at least one of a compound represented by Formula 1, a compound represented by Formula 2 or a mixture thereof dissolved in a solvent:

M⁺X⁻(YOₘRf)ₙ (1)
wherein M⁺ is an alkaline metal cation, and Rf is a C₁-C₄ perfluoroalkyl group, Y is carbon or sulfur, and X is oxygen, nitrogen or carbon, m=1 if Y is carbon, m=2 if Y is sulfur, n=1 if X is oxygen, n=2 if X is nitrogen, and n=3 if X is carbon; and

LiVW₄ (2)
wherein V is a Group 13 element, and W is a Group 17 element; and spin-coating the solution on a target layer.

According to another aspect of the present invention, there is provided a method of manufacturing a photovoltaic device, the method including:

forming a photoactive layer on a transparent substrate on which a first electrode is formed;

forming an electrode injecting layer by spin-coating a solution of compounds represented by Formula 1, Formula 2 or a mixture thereof dissolved in a solvent, on the photoactive layer; and

forming a second electrode on the EIL.

M⁺X⁻(YOₘRf)ₙ <Formula 1>

wherein M⁺ is an alkaline metal cation, and Rf is a C₁-C₄ perfluoroalkyl group, Y is carbon or sulfur, and X is oxygen, nitrogen or carbon, m=1 if Y is carbon, m=2 if Y is sulfur, n=1 if X is oxygen, n=2 if X is nitrogen, and n=3 if X is carbon; and

LiVW₄ <Formula 2>

wherein V is a Group 13 element, and W is a Group 17 element.

M⁺ may preferably be a lithium cation, a sodium cation, or a potassium cation.

Rf may be trifluoromethyl (CF₃—) group, pentafluoroethyl (C₂F₅—) group, heptafluoropropyl (C₃F₇—) group, or perfluorobutyl (C₄F₉—) group.

X⁻(YOₘRf)ₙ may be bistrifluoromethanesulfonylimide (N(SO₂CF₃)₂^{—}), bistrifluoromethanecarbonylimide (N(COCF₃)₂⁻), bispentafluoroethanesulfonimide (N(SOC₂F₅)₂⁻), bispentafluoroethanecarbonylimide (N(COC₂F₅)₂⁻), bisperfluorobutanesulfonylimide (N(SO₂C₄F₉)₂⁻), bisperfluorobutanecarbonylimide (N(COC₄F₉)₂⁻), tristrifluoromethanesulfonylmethide (C(SO₂CF₃)₃⁻), or tristrifluoromethanecarbonylmethide (C(COCF₃)₃⁻).

The compound represented by Formula 1 may be lithium bistrifluoromethanesulfonylimide, lithium bistrifluoromethanecarbonylimide, lithium bispentafluoroethanesulfonimide, lithium bispentafluoroethanecarbonylimide, lithium bisperfluorobutanesulfonylimide, lithium bisperfluorobutanecarbonylimide, lithium tristrifluoromethanesulfonylmethide, lithium tristrifluoromethanecarbonylmethide, sodium bistrifluoromethanesulfonylimide, sodium bistrifluoromethanecarbonylimide, sodium bispentafluoroethanesulfonimide, sodium bispentafluoroethanecarbonylimide, sodium bisperfluorobutanesulfonylimide, sodium bisperfluorobutanecarbonylimide, sodium tristrifluoromethanesulfonylmethide, sodium tristrifluoromethanecarbonylmethide, potassium bistrifluoromethanesulfonylimide, potassium bistrifluoromethanecarbonylimide, potassium bispentafluoroethanesulfonimide, potassium bispentafluoroethanecarbonylimide, potassium bisperfluorobutanesulfonylimide, potassium bisperfluorobutanecarbonylimide, potassium tristrifluoromethanesulfonylmethide, potassium tristrifluoromethanecarbonylmethide, or a mixture thereof.

V may be boron or aluminum.

W may be fluorine, chlorine, or bromine.

The compound represented by Formula 2 may be LiBF₄, LiBCl₄, LiBBr₄, LiAlF₄, LiAlCl₄ or LiAlBr₄.

The solvent may be a C₁-C₃ alcohol.

The solvent may be methanol, ethanol, propanol, isopropanol, or a mixture thereof.

The content of the compounds represented by Formulae 1 and 2 or a mixture thereof may be 1 to 20 wt % based on 100 wt % of the solvent.

According to another aspect of the present invention, there is provided an organic light-emitting device including the EIL between a first electrode and a second electrode.

The device may have a structure of first electrode/hole injecting layer/hole transporting layer/emitting layer/electron transporting layer/electron injecting layer/second electrode, or first electrode/hole injecting layer/hole transporting layer/emitting layer/hole blocking layer/electron transporting layer/electron injecting layer/second electrode.

### BRIEF DESCRIPTION OF THE DRAWINGS

The above and other features and advantages of the present invention will become more apparent by describing in detail exemplary embodiments thereof with reference to the attached drawings in which:

FIG. 1 is a partial cross-sectional view illustrating a photovoltaic device according to an embodiment of the present invention;

FIGS. 2A and 2B are cross-sectional views illustrating structures of conventional organic light-emitting devices;

FIG. 3 is a graph comparing the current-voltage characteristics of photovoltaic devices of Example 1 and Comparative Example 1; and

FIGS. 4A and 4B are graphs comparing the current-voltage characteristics and EL spectrums of organic light-emitting devices of Example 3 and Comparative Example 2.

### DETAILED DESCRIPTION OF THE INVENTION

The present invention provides an electron injecting layer (EIL) formed by simply spin-coating a solution of a superacid salt, a lithium salt or a mixture thereof dissolved in a solvent, a photovoltaic device including the same, a method of manufacturing the photovoltaic device, and an organic light-emitting device including the EIL.

The EIL according to the present invention includes a superacid salt, a lithium salt, or a mixture thereof, wherein the superacid salt may be a compound represented by Formula 1 below.

M⁺X⁻(YOₘRf)ₙ <Formula 1>

wherein M⁺ is an alkaline metal cation, and Rf is a C₁-C₄ perfluoroalkyl group, Y is carbon or sulfur, X is oxygen, nitrogen or carbon, m=1 if Y is carbon, and m=2 if Y is sulfur, n=1 if X is oxygen, n=2 if X is nitrogen, and n=3 if X is carbon;

The lithium salt may be represented by Formula 2 below:

LiVW₄ <Formula 2>

wherein V is a Group 13 element, and W is a Group 17 element.

M⁺ may be a monovalent metal cation, and may preferably be a monovalent alkaline cation such as lithium cation, a sodium cation, or a potassium cation.

Rf may be trifluoromethyl (CF₃—) group, pentafluoroethyl (C₂F₅—) group, heptafluoropropyl (C₃F₇—) group, or perfluorobutyl (C₄F₉—) group.

X⁻(YOₘRf)ₙ may non-exclusively include, in the case where X is nitrogen and y is sulfur, bistrifluoromethanesulfonylimide (N(SO₂CF₃)₂⁻), bispentafluoroethanesulfonimide (N(SOC₂F₅)₂⁻), and bisperfluorobutanesulfonylimide (N(SO₂C₄F₉)₂⁻), in the case where X is nitrogen and Y is carbon, bistrifluoromethanecarbonylimide (N(COCF₃)₂⁻), bispentafluoroethanecarbonylimide (N(COC₂F₅)₂⁻), and bisperfluorobutanecarbonylimide (N(COC₄F₉)₂⁻), in the case where X is carbon and Y is sulfur, tristrifluoromethanesulfonylmethide (C(SO₂CF₃)₃⁻), and in the case where X is carbon and Y is carbon, tristrifluoromethanecarbonylmethide (C(COCF₃)₃⁻).

More particularly, the compound represented by Formula 1 may be lithium bistrifluoromethanesulfonylimide, lithium bistrifluoromethanecarbonylimide, lithium bispentafluoroethanesulfonimide, lithium bispentafluoroethanecarbonylimide, lithium bisperfluorobutanesulfonylimide, lithium bisperfluorobutanecarbonylimide, lithium tristrifluoromethanesulfonylmethide, lithium tristrifluoromethanecarbonylmethide, sodium bistrifluoromethanesulfonylimide, sodium bistrifluoromethanecarbonylimide, sodium bispentafluoroethanesulfonimide, sodium bispentafluoroethanecarbonylimide, sodium bisperfluorobutanesulfonylimide, sodium bisperfluorobutanecarbonylimide, sodium tristrifluoromethanesulfonylmethide, sodium tristrifluoromethanecarbonylmethide, potassium bistrifluoromethanesulfonylimide, potassium bistrifluoromethanecarbonylimide, potassium bispentafluoroethanesulfonimide, potassium bispentafluoroethanecarbonylimide, potassium bisperfluorobutanesulfonylimide, potassium bisperfluorobutanecarbonylimide, potassium tristrifluoromethanesulfonylmethide, potassium tristrifluoromethanecarbonylmethide, or a mixture thereof, but is not limited thereto.

Meanwhile, V may be a Group 13 element, and preferably boron or aluminum. W may be a Group 17 element, and preferably be fluorine, chlorine, and bromine. More particularly, non-exclusive examples of the compound represented by Formula 2 may be LiBF₄, LiBCl₄, LiBBr₄, LiAlF₄, LiAlCl₄ and LiAlBr₄.

The compound represented by Formula 1, Formula 2 or a mixture thereof dissolves in an alcohol-based solvent, forming the EIL in a photovoltaic device or an organic light-emitting device using a spin-coating method.

Hereinafter, the photovoltaic device including the EIL according to the present invention between a first electrode and a second electrode that are disposed opposite to each other will be described more fully with reference to the accompanying drawings, in which preferred embodiments of the invention are shown.

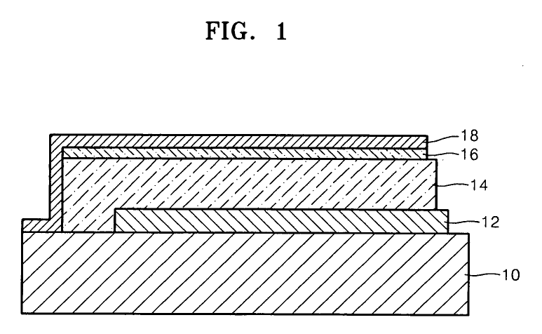

FIG. 1 is a partial cross-sectional view illustrating a photovoltaic device according to an embodiment of the present invention. Referring to FIG. 1, the photovoltaic device according to the current embodiment sequentially includes a transparent substrate 10 formed of glass or plastic, a first electrode 12 disposed thereon, a photoactive layer 14 including an organic compound, an EIL 16 and a second electrode 18. Such a photovoltaic device may be applied in various fields such as solar cells generating electrical energy by absorbing sunlight.

The first electrode 12 may be formed of a material having a high work function, and may be formed of a transparent material such as indium tin oxide (ITO), fluorine tin oxide (FTO), or indium zinc oxide (IZO) to admit light. In addition, the second electrode 18 may be formed of a metal having a low work function. The second electrode 18 may be formed of a single layer of Al, Ca, or Ag, or may include layers of different metals stacked in a multi-layer structure.

The photoactive layer 14 formed on the first electrode includes an electron donor material and an electron acceptor material. An additional layer (not shown) may be formed between the first electrode 12 and the photoactive layer 14, and the additional layer (not shown) may include a mixture of polyethylene dioxythiophene (PEDOT) and poly(styrene sulfonate) (PSS).

The photoactive layer 14 may be formed by a heterojunction of an electron donor material and an electron acceptor material, or may have a multilayered structure in which an electron donor material layer and an electron acceptor material layer are stacked.

Here, the electron donor material may preferably be a semiconductive polymer or a single organic molecule with strong photoabsorptive properties. Specific examples of such semiconductive polymer may include polyphenylene vinylene (PPV), polythiophene (PT), poly(3-hexylthiophene (P3HT), and poly(2-methoxy-5-(3′,7′-dimethyloctyloxy)-1,4-phenylene vinylene, (MOMD-PPV), and specific examples of the single organic molecule may include phthalocyanine-based compounds such as copper phthalocyanine (CuPc) or zinc phthalocyanine (ZnPc). In addition, the electron acceptor material may be fullerene (C₆₀), derivatives thereof, or perylene. Fullerene may be used mainly in combination with a semiconductive polymer, or may be applied in a multilayer structure.

The photoactive layer 14 may be formed using various methods such as spin casting, ink-jet, or screen-printing.

The EIL 16 may be formed between the photoactive layer 14 and the second electrode 18, and may include a superacid salt, a lithium salt, or a mixture thereof. The superacid salt and the lithium salt may be compounds represented by Formulae 1 and 2, respectively.

The EIL 16 may be formed using a method such as vacuum deposition, spin-coating, inkjet-printing, or screen printing, and preferably by spin-coating.

If the thickness of the EIL 16 is less than 10 Å, it becomes difficult to manufacture the layer to have a uniform thickness, and thus a thickness of 10 Å or greater is preferable, and a thickness of 20 to 100 Å is more preferable with regards to the efficiency of the photovoltaic device.

The EIL 16 according to the present invention, unlike a conventional LiF layer formed by vacuum deposition, is formed by spin-coating a superacid salt, a lithium salt, or a mixture thereof dissolved in a solvent, and thus the process is simple and is capable of effectively filling in the wells formed by a rough surface of the photoactive layer 14, on which the EIL 16 is formed.

The activity of the photovoltaic device of the present invention will now be described with reference to an organic solar cell used as an example of the photovoltaic device.

First, when light such as sunlight passes through a transparent substrate and a first electrode 12 to be admitted to the organic solar cell, electron-hole pairs are generated in an electron donor, and the generated electrons are transported to an electron acceptor, and thus the electrons and the holes are separated. The separation between the electrons and the holes occur by very rapid charge transportation called photo-induced charge transfer (TIPC) between an electron donor and an electron acceptor. The electrons and holes separated as such are injected in to the first electrode 12 and the second electrode 18 to generate electrical energy.

A photovoltaic device including an EIL according to the present invention may be manufactured as follows.

First, a photoactive layer is formed on a transparent substrate on which a first electrode is prepared, and an EIL is formed on the photoactive layer by spin-coating a solution of compounds represented by Formula 1 or 2 below or a mixture thereof dissolved in a solvent. Then a second electrode is formed on the EIL to complete the manufacture of the photovoltaic device.

M⁺X⁻(YOₘRf)ₙ <Formula 1>

LiVW₄ <Formula 2>

wherein M⁺, Rf, Y, X, m, n, V, and W are as previously described.

According to an embodiment of the present invention, X⁻(YOₘRf)ₙ may be bistrifluoromethanesulfonylimide (N(SO₂CF₃)₂⁻), bistrifluoromethanecarbonylimide (N(COCF₃)₂⁻), bispentafluoroethanesulfonimide (N(SOC₂F₅)₂⁻), bispentafluoroethanecarbonylimide (N(COC₂F₅)₂⁻), bisperfluorobutanesulfonylimide (N(SO₂C₄F₉)₂⁻), bisperfluorobutanecarbonylimide (N(COC₄F₉)₂⁻), tristrifluoromethanesulfonylmethide (C(SO₂CF₃)₃⁻), or tristrifluoromethanecarbonylmethide (C(COCF₃)₃⁻).

According to an embodiment of the present invention, the compound represented by Formula 1 may be lithium bistrifluoromethanesulfonylimide, lithium bistrifluoromethanecarbonylimide, lithium bispentafluoroethanesulfonimide, lithium bispentafluoroethanecarbonylimide, lithium bisperfluorobutanesulfonylimide, lithium bisperfluorobutanecarbonylimide, lithium tristrifluoromethanesulfonylmethide, lithium tristrifluoromethanecarbonylmethide, sodium bistrifluoromethanesulfonylimide, sodium bistrifluoromethanecarbonylimide, sodium bispentafluoroethanesulfonimide, sodium bispentafluoroethanecarbonylimide, sodium bisperfluorobutanesulfonylimide, sodium bisperfluorobutanecarbonylimide, sodium tristrifluoromethanesulfonylmethide, sodium tristrifluoromethanecarbonylmethide, potassium bistrifluoromethanesulfonylimide, potassium bistrifluoromethanecarbonylimide, potassium bispentafluoroethanesulfonimide, potassium bispentafluoroethanecarbonylimide, potassium bisperfluorobutanesulfonylimide, potassium bisperfluorobutanecarbonylimide, potassium tristrifluoromethanesulfonylmethide, potassium tristrifluoromethanecarbonylmethide, or a mixture thereof.

According to an embodiment of the present invention, the compound represented by Formula 2 may be LiBF₄, LiBCl₄, LiBBr₄, LiAlF₄, LiAlCl₄ or LiAlBr₄.

In the method described above, the solvent may be a C₁-C₃ alcohol, and may preferably be methanol, ethanol, propanol, isopropanol, or a mixture thereof.

The content of the compounds represented by Formula 1, 2 or a mixture thereof dissolved in the solvent may be 1 to 20 wt % based on 100 wt % of the solvent. A viscosity suitable for spin-coating is formed within such a range.

Next, an embodiment of an organic light-emitting device including the EIL according to the present invention between the first electrode and the second electrode will be described with reference to the accompanying drawings.

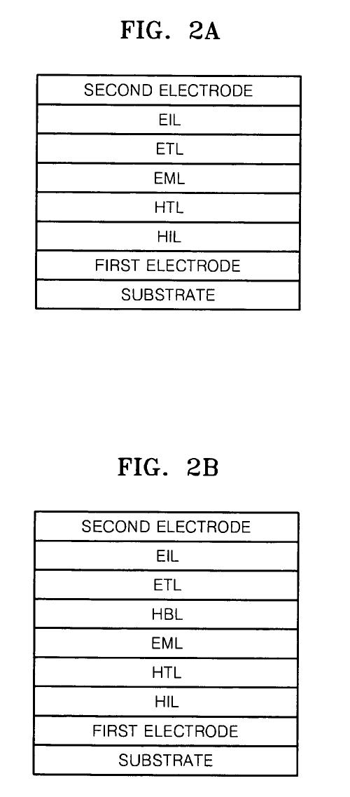

FIGS. 2A and 2B are cross-sectional views illustrating structures of conventional organic light-emitting devices. The organic light-emitting device of FIG. 2A may have a structure of first electrode/hole injecting layer/hole transporting layer/emitting layer/electron transporting layer/electron injecting layer/second electrode, and the organic light-emitting device of FIG. 2B may have a structure of first electrode/hole injecting layer/hole transporting layer/emitting layer/hole blocking layer/electron transporting layer/electron injecting layer/second electrode. Here, the EIL may include compounds represented by Formula 1, 2 or a mixture thereof.

First, an anode forming material having a high work function is deposited on a substrate using deposition or sputtering to form an anode, and the anode may constitute the first electrode. The substrate may be a substrate conventionally used in organic EL devices, and may preferably be a glass substrate or a plastic substrate having excellent transparency, surface planarity, ease of handling, and water resistance. The anode forming material may be ITO, IZO, SnO₂, or ZnO, which are transparent and highly conductive.

A hole injecting layer forming material is then vacuum thermodeposited or spin-coated on the anode. The hole injecting layer forming material may be, for example, CuPc (shown below), a phthalocyanine compound such as copper phthalocyanine disclosed in U.S. Pat. No. 4,356,429, or a starburst-type amine derivative such as TCTA (shown below), m-MTDATA (shown below), or m-MTDAPB, or conductive polymers with solubility such as polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), or polyaniline/poly 4-styrene- sulfonate (Pani/PSS), but is not limited thereto.

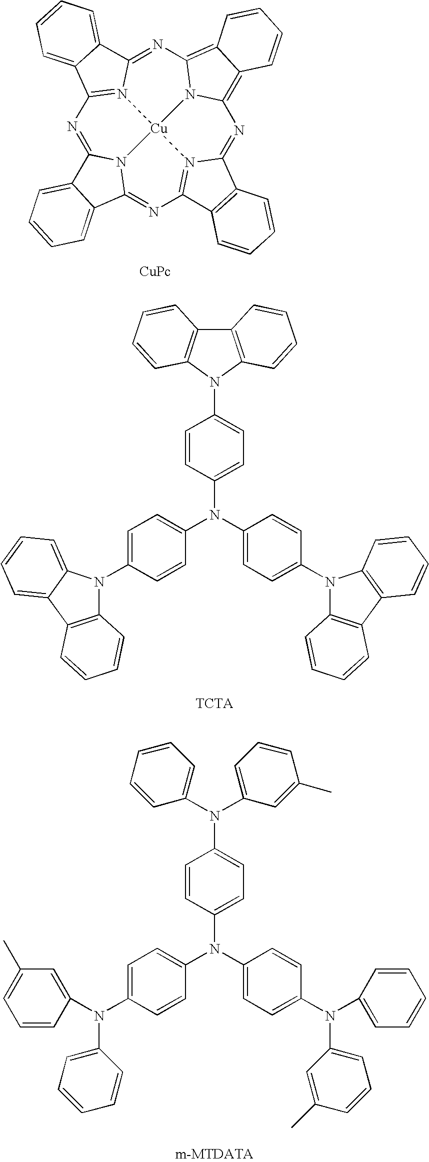

A hole transporting layer-forming material is vacuum thermodeposited or spin-coated on the hole injecting layer to form a hole transporting layer. The hole transporting layer-forming material may be, for example, 1,3,5-tricarbazolylbenzene, 4,4′-biscarbazolylbiphenyl, polyvinyl carbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)benzene, 1,3,5-tris(2-carbazolyl-5-methoxyphenyl)benzene, bis(4-carbazolyl)silane, N,N′-bis(3-methylphenyl)-N,N′-diphenyl-[1,1-biphenyl]-4,4′-diamine (TPD), N,N′-di(naphthalen-1-yl)-N,N′-diphenyl benzidine (α-NPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine (TFB), or poly(9,9-dioctylfluorene-co-bis-(4-butylphenyl-bis-N,N-phenyl-1,4-phenylenediamine (PFB), but is not limited thereto.

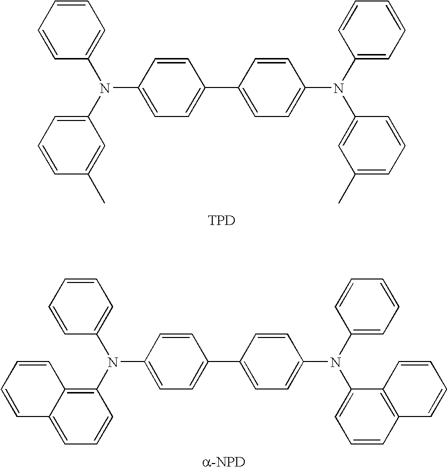

Next, an emitting layer is formed on the hole transporting layer. The emitting layer-forming material is not particularly limited, and may include a host such as 4,4′-biscarbazolylbiphenyl (CBP), TCB, TCTA, SDI-BH-18, SDI-BH-19, SDI-BH-22, SDI-BH-23, dmCBP, Liq, TPBI, Balq, or BCP, and a fluorescent dopant such as IDE102 or IDE105 which are available from Idemitsu Co., or a green phosphorescent dopant Ir(ppy)₃, or a blue phosphorescent dopant (4,6-F₂ppy)₂Irpic well known as phosphorescent dopants may be vacuum thermodeposited together. These compounds are represented by the structures shown below.

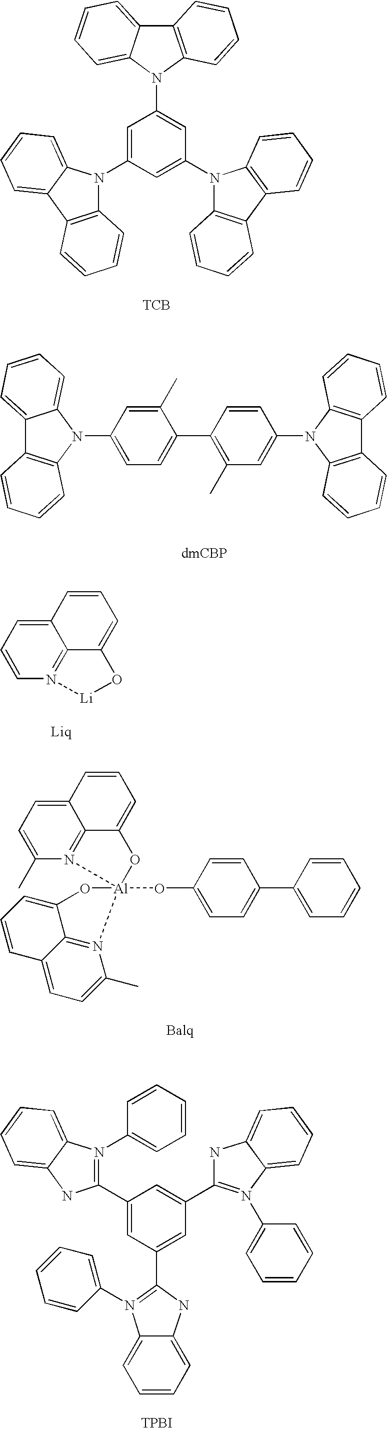

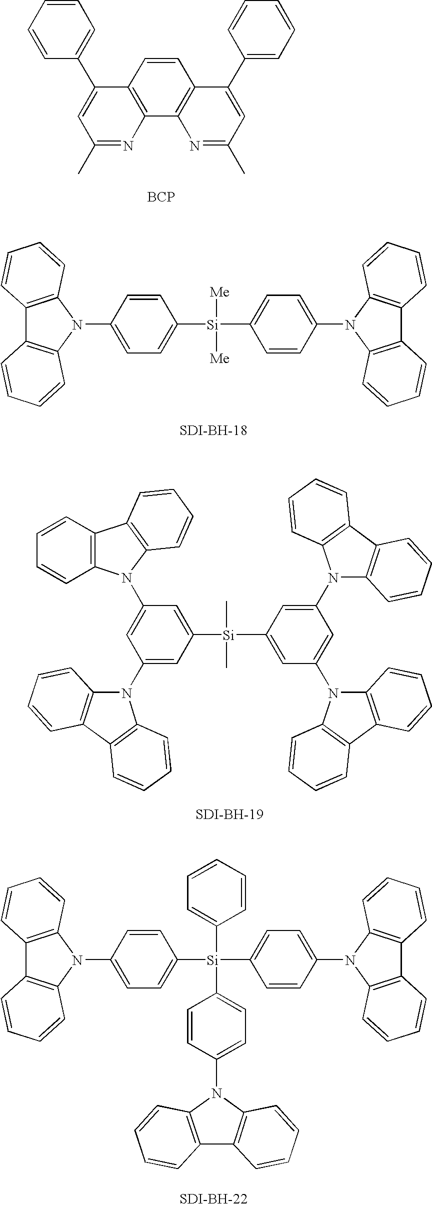

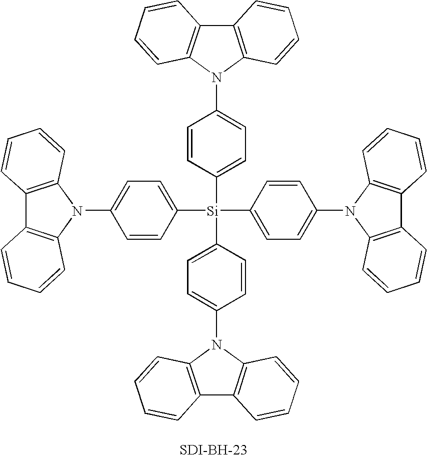

The doping concentration is not particularly limited, but may conventionally be within the range of 0.5-12 wt %. A relatively thin electron transporting layer may be formed on the emitting layer by vacuum deposition or spin-coating.

Meanwhile, if phosphorescent dopants are used in the emitting layer, a hole blocking layer-forming material may be additionally vacuum thermodeposited on the electron transporting layer to form a hole blocking layer, in order to prevent diffusion of triplet excitons or holes into the electron transporting layer. The hole blocking layer material is not particularly limited, but must have a higher ionizing potential than an electroluminescent compound while possessing electron transporting abilities. In this regard, the hole blocking layer material may include Balq or BCP.

A relatively thin electron transporting layer may be formed on the hole blocking layer by vacuum deposition or spin-coating. The electron transporting layer material may be a conventionally used material such as Alq₃.

An EIL including a superacid salt, a lithium salt, or a mixture thereof according to the present invention may be formed on the electron transporting layer. Such an EIL may be formed using a method such as vacuum deposition, spin-coating, inkjet printing, or screen printing, but may preferably be formed using spin-coating.

The superacid salt may be a compound represented by Formula 1 below.

M⁺X⁻(YOₘRf)ₙ <Formula 1>

wherein M⁺ is an alkaline metal cation, and Rf is a C₁-C₄ perfluoroalkyl group,

if Y is carbon, m=1, and if Y is sulfur, m=2, if X is oxygen, n=1, if X is nitrogen, n=2, and if X is carbon, n=3;

The lithium salt may be represented by Formula 2 below:

LiVW₄ <Formula 2>

wherein V is a Group 13 element, and W is a Group 17 element.

M⁺ may be a monovalent metal cation, and may preferably be lithium cation, a sodium cation, or a potassium cation.

Rf may be trifluoromethyl (CF₃⁻) group, pentafluoroethyl (C₂F₅⁻) group, heptafluoropropyl (C₃F₇⁻) group, heptafluoroisopropyl ((CF₃)₂FC⁻) or perfluorobutyl (C₄F₉⁻) group.

X⁻(YOₘRf)ₙ may non-exclusively include, in the case where X is nitrogen and Y is sulfur, bistrifluoromethanesulfonylimide (N(SO₂CF₃)₂⁻), bispentafluoroethanesulfonimide (N(SOC₂F₅)₂⁻), and bisperfluorobutanesulfonylimide (N(SO₂C₄F₉)₂⁻), in the case where X is nitrogen and Y is carbon, bistrifluoromethanecarbonylimide (N(COCF₃)₂⁻), bispentafluoroethanecarbonylimide (N(COC₂F₅)₂⁻), and bisperfluorobutanecarbonylimide (N(COC₄F₉)₂⁻), in the case where X is carbon and Y is sulfur, tristrifluoromethanesulfonylmethide (C(SO₂CF₃)₃⁻), and in the case where X is carbon and Y is carbon, tristrifluoromethanecarbonylmethide (C(COCF₃)₃⁻).

More particularly, the compound represented by Formula 1 may be lithium bistrifluoromethanesulfonylimide, lithium bistrifluoromethanecarbonylimide, lithium bispentafluoroethanesulfonimide, lithium bispentafluoroethanecarbonylimide, lithium bisperfluorobutanesulfonylimide, lithium bisperfluorobutanecarbonylimide, lithium tristrifluoromethanesulfonylmethide, lithium tristrifluoromethanecarbonylmethide, sodium bistrifluoromethanesulfonylimide, sodium bistrifluoromethanecarbonylimide, sodium bispentafluoroethanesulfonimide, sodium bispentafluoroethanecarbonylimide, sodium bisperfluorobutanesulfonylimide, sodium bisperfluorobutanecarbonylimide, sodium tristrifluoromethanesulfonylmethide, sodium tristrifluoromethanecarbonylmethide, potassium bistrifluoromethanesulfonylimide, potassium bistrifluoromethanecarbonylimide, potassium bispentafluoroethanesulfonimide, potassium bispentafluoroethanecarbonylimide, potassium bisperfluorobutanesulfonylimide, potassium bisperfluorobutanecarbonylimide, potassium tristrifluoromethanesulfonylmethide, potassium tristrifluoromethanecarbonylmethide, or a mixture thereof, but is not limited thereto.

V may be a Group 13 element, and preferably boron or aluminum. Additionally, W may be a Group 17 element, and preferably be fluorine, chlorine, and bromine.

More particularly, non-exclusive examples of the compound represented by Formula 2 may be LiBF₄, LiBCl₄, LiBBr₄, LiAlF₄, LiAlCl₄ and LiAlBr₄.

Furthermore, a cathode is formed by vacuum thermodepositing a cathode-forming metal on the EIL to complete the manufacture of the organic light-emitting device. The cathode-forming metal may be Li, Mg, Al, Al—Li, Ca, Mg—In, Mg—Ag, or the like. The cathode may constitute the second electrode. Moreover, a transparent cathode including ITO or IZO may be formed in order to obtain a single layered top-emission light-emitting device if necessary. Additionally, an anode or a double-layered intermediate layer may further be formed in the organic light-emitting device.

An organic solar cell and an organic light-emitting device including the EIL including the superacid salt, lithium salt, or a mixture thereof according to the present invention will now be described in more detail with reference to the following examples. However, these examples are for illustrative purposes only and are not intended to limit the scope of the invention.

### EXAMPLES

Preparation of Superacid Solution

1 g of lithium bistrifluoromethanesulfonylimide and 10 g of methanol were added to a 20 ml round-bottomed flask, and stirred for 60 minutes to prepare a uniform electron injecting layer (EIL) forming composition.

Preparation of Lithium Solution

0.1 g of lithium tetraborate and 10 g of methanol were added to a 20 ml round-bottomed flask and stirred for 60 minutes to prepare an EIL forming composition.

### Example 1

### Manufacturing of Organic Solar Cell

The lithium bistrifluoromethanesulfonylimide methanol solution was spin-coated to manufacture an organic solar cell having the following structure: ITO/PEDOT:pss(40 nm)/P3HT:PCBM(1:0.8)(180 nm)/LiTFSI(8 nm)/Al(150 nm)

A layer including a mixture of poly(3,4-ethylenedioxythiophene) and poly(styrene-sulfonate) was formed on a first electrode formed of indium tin oxide, and a photoactive layer including poly(3-hexylthiophene) and 1-(3-methoxy-carbonyl) propyl-1-phenyl(6,6)C61 was formed to a thickness of 180 nm on the mixed layer. Here, the weight ratio between the poly(3-hexylthiophene) and the 1-(3-methoxy-carbonyl) propyl-1-phenyl(6,6)C61 was 1:0.8.

Additionally, the lithium bistrifluoromethanesulfonylimide methanol solution was spin-coated on a target layer (i.e., the photoactive layer in Example 1) to form an EIL having a thickness of 50 Å, and a second electrode including Al was formed to a thickness of 150 nm on the EIL, thereby completing the manufacture of an organic solar cell. Then a heat treatment process was performed at a temperature of 150° C. for 30 minutes after the formation of the second electrode in order to enhance the characteristics of the completed device. The organic solar cell was 1.4 mm in width and 1.4 mm in length.

### Example 2

### Manufacturing of Organic Solar Cell

An organic solar cell was manufactured using the same method as in Example 1, except that lithium tetraborate methanol solution was used instead of lithium bistrifluoromethanesulfonylimide.

### Example 3

### Manufacturing of Organic Light-emitting Device

The lithium bistrifluoromethanesulfonylimide methanol solution was spin-coated to manufacture an organic light-emitting device having the following structure: m-MTDATA(750 Å)/α-N PD(150 Å)/DSA(300 Å):TBPe(3%)/Alq3(200 Å)/LiTFSI(80 Å)/Al(1500 Å)

For the anode, a Corning 15 Ω/cm² (1200 Å) ITO glass substrate was cut into a size of 50 mm×50 mm×0.7 mm and washed by sonicating in isopropyl alcohol and deionized water for 5 minutes each, and then treated with UV ozone for 30 minutes. m-MTDATA was vacuum-deposited on the anode to form a hole injecting layer having a thickness of 750 Å. Next, α-NPD was vacuum-deposited on the hole injection layer to a thickness of 150 Å to form a hole transporting layer. After forming the hole transporting layer, DSA as a host and 3% TBPe as a dopant were deposited on the hole transporting layer to form an emitting layer having a thickness of 300 Å. Then, Alq3 was vacuum-deposited on the emitting layer to form an electron transporting layer having a thickness of 200 Å. The lithium bistrifluoromethanesulfonylimide (LiTFSI) methanol solution was spin-coated on a target layer (i.e., the electron transporting layer in Example 3) to form a LiTFSI electron injecting layer having a thickness of 80 Å, and Al (cathode) was then vacuum-deposited to a thickness of 1500 Å, forming a LiTFSI/Al electrode, thereby completing the manufacture of the organic light-emitting device as shown in FIG. 2A.

### Example 4

### Manufacturing of Organic Light-Emitting Device

An organic light-emitting device was manufactured using the same method as in Example 3, except that lithium tetraborate methanol solution was used instead of lithium bistrifluoromethanesulfonylimide.

### Comparative Example 1

### Manufacturing of Organic Solar Cell

An organic solar cell having the following structure was manufactured using the same method as in Example 1, except that the EIL was not formed: ITO/PEDOT:pss(40 nm)/P3HT:PCBM(1:0.8)(180 nm)/Al(150 nm)

### Comparative Example 2

### Manufacturing of Organic Light-Emitting Device

An organic light-emitting device having the following structure was manufactured using the same method as in Example 3, except that LiF was vacuum-deposited to a thickness of 5 Å to form the EIL. m-MTDATA(750 Å)/α-NPD(150 Å)/DSA(300 Å):TBPe(3%)/Alq3(200 Å)/LiF(5 Å)/Al(1500 Å)

### Evaluation Example

Comparison of Photovoltaic Device Characteristics

Photocurrent density (Jsc), open voltage (Voc), filling factor (FF), and efficiency of the organic solar cells of Example 1 and Comparative Example 1 were measured, and the results are shown in Table 1 below.

TABLE 1

| | Jsc (mA/cm²) | Voc (V) | FF (%) | Efficiency (%) |
|---|---|---|---|---|
| Example 1 | 9.49 | 0.60 | 49.7 | 2.83 |
| Comparative | 9.23 | 0.60 | 42.0 | 2.32 |
| Example 1 | | | | |

Comparing the organic solar cells of Example 1 and Comparative Example 1, it can be seen that Jsc and FF are higher in Example 1, and thus the efficiency is significantly better in Example 1, in the presence of the LITFSI layer. The improvement of FF shows that the contact characteristics of the interface between the photoactive layer and the metal layer (second electrode) is improved, and this is because of an effective filling of surface wells on the organic active layer caused by roughness, by spin-coating.

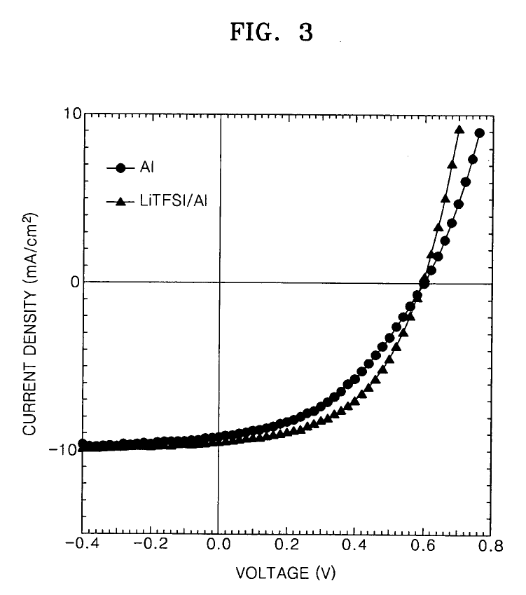

Additionally, the current-voltage characteristics of the photovoltaic devices of Example 1 and Comparative Example 1 were compared and the results are shown in FIG. 3.

Referring to FIG. 3, it can be seen that the organic solar cell according to Example 1 has a higher current density than the organic solar cell according to Comparative Example 1, at a voltage of 0.6 V or higher.

The organic solar cells have been described as examples of photovoltaic devices, but the present invention is not limited thereto, and may be applied in various photovoltaic devices.

Comparison of Organic Light-Emitting Devices

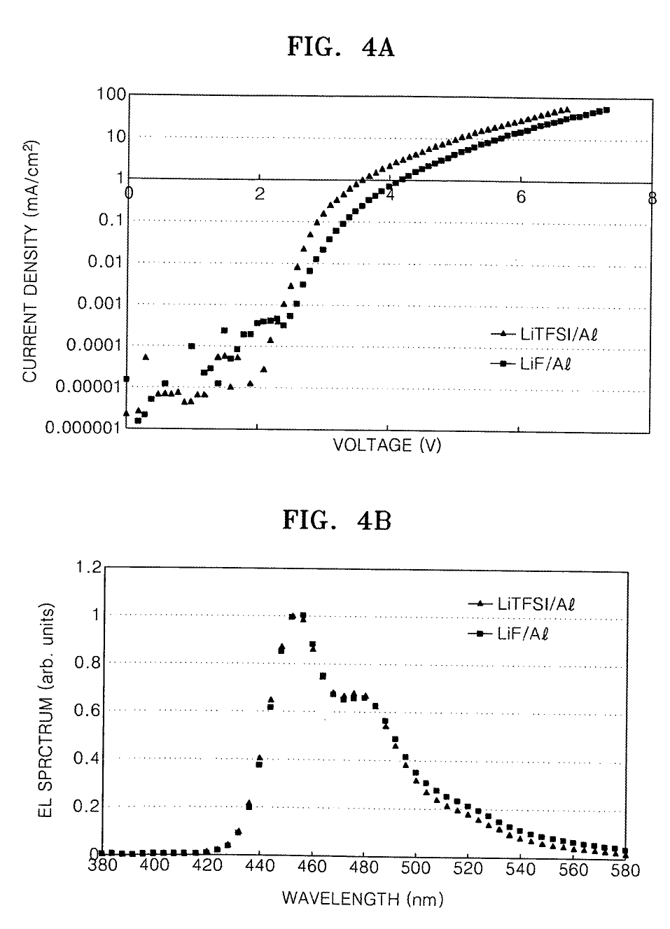

Current-voltage characteristics and EL spectrums of the devices according to Example 3 and Comparative Example 2 were evaluated and the results were shown in FIGS. 4A and 4B. Keithley was used for the evaluation of the current-voltage characteristics.

FIGS. 4A and 4B are graphs comparing the current-voltage characteristics and EL spectrums of the organic light-emitting devices of Example 3 and Comparative Example 2.

Referring to the current-voltage characteristic comparison graph of FIG. 4A, it can be seen that the LiTFSi in the LiTFSi/Al device (Example 3) had better electron injecting characteristics than that of LiF in the LiF/Al device (Comparative Example 2).

In particular, as seen in the EL spectrum of FIG. 4B, the LiF/Al device shows greater light-emission than the LiTFSi/Al device in the range of 500 nm or more. Therefore, the LiF/Al device has lower color purity than the LiTFSi/Al device. This is because electron injection is relatively more difficult for the LiF/Al device compared to the LiTFSi/Al device, and as a result, a part of the electron-hole recombination zone exists in the back of the electron transporting layer (Alq3) region.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An electron injecting layer comprising at least one of a superacid salt represented by Formula 1, a lithium salt represented by Formula 2 and a mixture of the compounds represented by Formulae 1 and 2:
M⁺X⁻(YOₘRf)ₙ (1)
wherein M⁺ is an alkaline metal cation, Rf is a C₁-C₄ perfluoroalkyl group, Y is carbon or sulfur, X is oxygen, nitrogen or carbon, m=1 if Y is carbon, m=2 if Y is sulfur, n=1 if X is oxygen, n=2 if X is nitrogen, and n=3 if X is carbon; and
LiVW₄ (2)
wherein V is a Group 13 element, and W is a Group 17 element.

2. The electron injecting layer of claim 1, wherein the electron injecting layer comprises the superacid salt represented by Formula 1.

3. The electron injecting layer of claim 2, wherein M⁺ is one selected from the group consisting of a lithium cation, sodium cation, and potassium cation, and Rf is one selected from the group consisting of a trifluoromethyl (CF₃—) group, a pentafluoroethyl (C₂F₅—) group, a heptafluoropropyl (C₃F₇—) group, and a perfluorobutyl (C₄F₉—) group.

4. The electron injecting layer of claim 2, wherein X⁻(YOₘRf)ₙ is one selected from the group consisting of bistrifluoromethanesulfonylimide (N(SO₂CF₃)₂⁻), bistrifluoromethanecarbonylimide (N(COCF₃)₂⁻), bispentafluoroethanesulfonimide (N(SOC₂F₅)₂⁻), bispentafluoroethanecarbonylimide (N(COC₂F₅)₂⁻), bisperfluorobutanesulfonylimide (N(SO₂C₄F₉)₂⁻), bisperfluorobutanecarbonylimide (N(COC₄F₉)₂⁻), tristrifluoromethanesulfonylmethide (C(SO₂CF₃)₃⁻), and tristrifluoromethanecarbonylmethide (C(COCF₃)₃⁻).

5. The electron injecting layer of claim 2, wherein the compound represented by Formula 1 is one selected from the group consisting of lithium bistrifluoromethanesulfonylimide, lithium bistrifluoromethanecarbonylimide, lithium bispentafluoroethanesulfonimide, lithium bispentafluoroethanecarbonylimide, lithium bisperfluorobutanesulfonylimide, lithium bisperfluorobutanecarbonylimide, lithium tristrifluoromethanesulfonylmethide, lithium tristrifluoromethanecarbonylmethide, sodium bistrifluoromethanesulfonylimide, sodium bistrifluoromethanecarbonylimide, sodium bispentafluoroethanesulfonimide, sodium bispentafluoroethanecarbonylimide, sodium bisperfluorobutanesulfonylimide, sodium bisperfluorobutanecarbonylimide, sodium tristrifluoromethanesulfonylmethide, sodium tristrifluoromethanecarbonylmethide, potassium bistrifluoromethanesulfonylimide, potassium bistrifluoromethanecarbonylimide, potassium bispentafluoroethanesulfonimide, potassium bispentafluoroethanecarbonylimide, potassium bisperfluorobutanesulfonylimide, potassium bisperfluorobutanecarbonylimide, potassium tristrifluoromethanesulfonylmethide, potassium tristrifluoromethanecarbonylmethide, and a mixture thereof.

6. The electron injecting layer of claim 1, wherein the electron injecting layer comprises the lithium salt represented by Formula 2.

7. The electron injecting layer of claim 6, wherein the compound represented by Formula 2 is one selected from the group consisting of LiBF₄, LiBCl₄, LiBBr₄, LiAlF₄, LiAlCl₄ and LiAlBr₄.

8. A photovoltaic device comprising the electron injecting layer according to claim 1 between a first electrode and a second electrode.

9. An organic light-emitting device comprising the electron injecting layer according to claim 1 between a first electrode and a second electrode.

10. An electron injecting layer of a photovoltaic device or an organic light-emitting device, the electron injecting layer comprising at least one of a superacid salt represented by Formula 1, a lithium salt represented by Formula 2 and a mixture of the compounds represented by Formulae 1 and 2:
M⁺X⁻(YOₘRf)ₙ (1)
wherein M⁺ is a lithium cation, sodium cation, and potassium cation, and Rf is a C₁-C₄ perfluoroalkyl group, and X⁻(YOₘRf)ₙ is one selected from the group consisting of bistrifluoromethanesulfonylimide (N(SO₂CF₃)₂⁻), bistrifluoromethanecarbonylimide (N(COCF₃)₂⁻), bispentafluoroethanesulfonimide (N(SOC₂F₅)₂⁻), bispentafluoroethanecarbonylimide (N(COC₂F₅)₂⁻), bisperfluorobutanesulfonylimide (N(SO₂C₄F₉)₂⁻), bisperfluorobutanecarbonylimide (N(COC₄F₉)₂⁻), tristrifluoromethanesulfonylmethide (C(SO₂CF₃)₃⁻), and tristrifluoromethanecarbonylmethide (C(COCF₃)₃⁻); and
LiVW₄ (2)
wherein V is boron or aluminum, and W is one of fluorine, chlorine and bromine.

11. A method of manufacturing an electron injecting layer, the method comprising:
preparing a solution including at least one of a compound represented by Formula 1, a compound represented by Formula 2 or a mixture thereof dissolved in a solvent:
M⁺X⁻(YOₘRf)ₙ (1)
wherein M⁺ is an alkaline metal cation, and Rf is a C₁-C₄ perfluoroalkyl group, Y is carbon or sulfur, and X is oxygen, nitrogen or carbon, m=1 if Y is carbon, m=2 if Y is sulfur, n=1 if X is oxygen, n=2 if X is nitrogen, and n=3 if X is carbon; and
LiVW₄ (2)
wherein V is a Group 13 element, and W is a Group 17 element; and
spin-coating the solution on a target layer.

12. A method of manufacturing a photovoltaic device, the method comprising:
preparing a first electrode formed on a transparent substrate;
forming a photoactive layer on the first electrode;
forming the electrode injecting layer on the photoactive layer by the method of claim 11, wherein the target layer is the photoactive layer; and
forming a second electrode on the electron injecting layer.

13. A method of manufacturing an organic light-emitting device, the method comprising:
preparing a first electrode formed on a substrate;
forming an emitting layer on the first electrode;
forming an electron transporting layer on the emitting layer;
forming the electron injecting layer on the electron transporting layer by the method of claim 11, wherein the target layer is the electron transporting layer; and
forming a second electrode on the electron injecting layer.

14. The method of claim 11, wherein the solution includes the compound represented by Formula 1.

15. The method of claim 14, wherein M⁺ is one selected from the group consisting of a lithium cation, sodium cation, and potassium cation, and Rf is one selected from the group consisting of a trifluoromethyl (CF₃—) group, a pentafluoroethyl (C₂F₅—) group, a heptafluoropropyl (C₃F₇—) group, and a perfluorobutyl (C₄F₉—) group.

16. The method of claim 14, wherein X⁻(YOₘRf)ₙ is one selected from the group consisting of bistrifluoromethanesulfonylimide (N(SO₂CF₃)₂⁻), bistrifluoromethanecarbonylimide (N(COCF₃)₂⁻), bispentafluoroethanesulfonimide (N(SOC₂F₅)₂⁻), bispentafluoroethanecarbonylimide (N(COC₂F₅)₂⁻), bisperfluorobutanesulfonylimide (N(SO₂C₄F₉)₂⁻), bisperfluorobutanecarbonylimide (N(COC₄F₉)₂⁻), tristrifluoromethanesulfonylmethide (C(SO₂CF₃)₃⁻), and tristrifluoromethanecarbonylmethide (C(COCF₃)₃⁻).

17. The method of claim 14, wherein the compound represented by Formula 1 is one selected from the group consisting of lithium bistrifluoromethanesulfonylimide, lithium bistrifluoromethanecarbonylimide, lithium bispentafluoroethanesulfonimide, lithium bispentafluoroethanecarbonylimide, lithium bisperfluorobutanesulfonylimide, lithium bisperfluorobutanecarbonylimide, lithium tristrifluoromethanesulfonylmethide, lithium tristrifluoromethanecarbonylmethide, sodium bistrifluoromethanesulfonylimide, sodium bistrifluoromethanecarbonylimide, sodium bispentafluoroethanesulfonimide, sodium bispentafluoroethanecarbonylimide, sodium bisperfluorobutanesulfonylimide, sodium bisperfluorobutanecarbonylimide, sodium tristrifluoromethanesulfonylmethide, sodium tristrifluoromethanecarbonylmethide, potassium bistrifluoromethanesulfonylimide, potassium bistrifluoromethanecarbonylimide, potassium bispentafluoroethanesulfonimide, potassium bispentafluoroethanecarbonylimide, potassium bisperfluorobutanesulfonylimide, potassium bisperfluorobutanecarbonylimide, potassium tristrifluoromethanesulfonylmethide, potassium tristrifluoromethanecarbonylmethide, and a mixture thereof.

18. The method of claim 11, wherein the solution includes the compound represented by Formula 2.

19. The method of claim 18, wherein the compound represented by Formula 2 is one selected from the group consisting of LiBF₄, LiBCl₄, LiBBr₄, LiAlF₄, LiAlCl₄ and LiAlBr₄.

20. The method of claim 11, wherein the solvent is a C₁-C₃ alcohol.

21. The method of claim 12, wherein the content of said at least one of the compound represented by Formula 1, the compound represented by Formula 2 and the mixture thereof is 1 to 20 wt % based on 100 wt % of the solvent.
